(19) United States
(12) Patent Application Publication
(10) Pub. No.: US 2026/0190591 A1
(43) Pub. Date: Jul. 2, 2026

(54) LIGHT EMITTING DISPLAY DEVICE

(71) Applicant: LG Display Co., Ltd., Seoul (KR)

(72) Inventors: Taehyeon Kim, Paju-si (KR); Seungkyeom Kim, Paju-si (KR); Hyemin Park, Paju-si (KR); KyungMin Kim, Paju-si (KR)

(73) Assignee: LG Display Co., Ltd., Seoul (KR)

(21) Appl. No.: 19/222,474

(22) Filed: May 29, 2025

(30) Foreign Application Priority Data
Dec. 31, 2024 (KR) 10-2024-0201620

(51) Int. Cl. H10H 29/856; H10H 29/49; H10K 59/131; H10K 59/80

(52) U.S. Cl. CPC H10H 29/856; H10H 29/49; H10K 59/131; H10K 59/878

(57) ABSTRACT

The present disclosure relates to a light emitting display device. A light emitting display device according to the present disclosure comprises: a substrate; a first pixel and a second pixel neighboring each other on the substrate; a planarization layer covering the first pixel and the second pixel; a bank on the planarization layer; a first slit formed at the planarization layer between the first pixel and the second pixel; and a second slit at the bank between the first pixel and the second pixel. The first slit and the second slit are arranged to be offset by a predetermined distance.

### CROSS-REFERENCE TO RELATED APPLICATION

This application claims the priority benefit of Korean Patent Application No. 10-2024-0201620, filed on Dec. 31, 2024, which is hereby incorporated by reference in its entirety.

### BACKGROUND

### Technical Field

The present disclosure relates to a light emitting display device. In particular, the present disclosure relates to a bottom emission type light emitting display device having micro mirrors to enhance the light extraction efficiency.

### Discussion of the Related Art

Among the display devices, light emitting display devices may have the advantages of a wide viewing angle, excellent contrast, and fast response speed. The light emitting element used in a light emitting display device may have a light emitting layer made of organic or inorganic material between the anode electrode and the cathode electrode.

In the light emitting element, holes are supplied from the anode electrode and electrons are supplied from the cathode electrode, and then the electrons and holes combine at the emission layer to generate excitons. As the excitons change from the excited state to the ground state, the fluorescent molecules in the emission layer may emit light to express color.

Some of the light emitted from the emission layer of the light emitting display device may not be emitted to the outside and may be lost due to total reflection within the electrode layer having a high refractive index, or due to total reflection occurring at the interface between the emission layer and the electrodes and/or the interface between the substrate and the air. This may result in a problem of reduced light extraction efficiency.

To overcome these problems, methods are being developed to improve the light extraction efficiency of light emitting devices by forming microlenses or microcavity structures inside the devices. However, although these structures improve the luminous efficiency of light emitted in the vertical direction of the display device, they cannot extract light emitted in the horizontal direction to the vertical direction. Therefore, existing methods have limitations in improving light extraction efficiency.

### SUMMARY

Accordingly, the present disclosure is directed to a light emitting display device that substantially obviates one or more problems due to limitations and disadvantages of the related art.

An object of the present disclosure, as for solving the problems described above, is to provide a bottom emission type light emitting display device that maximizes or enhances light extraction efficiency by extracting light generated from the emission layer to the outside, which would otherwise be trapped inside the device and disappear due to total reflection.

Another object of the present disclosure is to provide a bottom emission type light emitting display device that improves brightness rate and light extraction efficiency by arranging a micro mirror structure on the edge of the light emitting area to maximize or increase the area of the light emitting area. In particular, the present disclosure provides a bottom emission type light emitting display device that improves light extraction efficiency and enhances brightness per power consumption by extracting light that may be extinguished by an electric field from the central portion of the anode electrode to the outside.

Additional objects and features of the present disclosure can be clearly understood by those skilled in the art from the following description of the present disclosure.

To achieve these and other advantages and in accordance with the purpose of the disclosure, as embodied and broadly described herein,, a light emitting display device includes: a substrate, an emission area, a non-emission area, a planarization layer, a light blocking layer, an anode electrode, an emission layer and a cathode electrode. The substrate has a plurality of pixels. The emission area is disposed in each pixel. The non-emission area is disposed around the emission area. The planarization layer is disposed on the substrate, and has a flat portion corresponding to the non-emission area and a protrusion portion corresponding to the emission area on the flat portion. The light blocking layer is disposed between the planarization layer and substrate at the non-emission area, and has an inclined angle with respect to a surface of the substrate. The anode electrode is disposed on a top surface of the protrusion portion. The emission layer is disposed on the anode electrode. The cathode electrode is disposed on the emission layer.

In an example embodiment, the light blocking layer includes a first light blocking layer disposed at the non-emission area and a second light blocking layer near to the first light blocking layer in the non-emission area.

In an example embodiment, the first light blocking layer has a line shape along one side of the emission area. The second light blocking layer is parallel to the first light emitting layer with a predetermined distance.

In an example embodiment, the light emitting display device further includes a pattern layer having a first height and disposed between the light blocking layer and the substrate. The light blocking layer includes a first layer on one side of the pattern layer.

The light emitting display device according to the present disclosure may have a structure in which almost all of the lights emitted from the emission layer may be extracted to the outside without being trapped and extinguished inside of the device, thereby providing a bottom emission type light emitting display device with maximized or enhanced light extraction efficiency.

The light emitting display device according to the present disclosure may provide a bottom emission type light emitting display device that minimizes or reduces non-emission areas and improve light extraction efficiency by arranging micro mirrors (or reflectors) without using a bank covering the circumferences of the pixel electrode.

The light emitting display device according to the present disclosure may have a light shielding layer arranged so as to be vertically inclined between pixels. The light shielding layer having an inclination angle may block the lights provided from the emission layer from being reflected by the substrate and entering into a neighboring pixel. As a result, a light emitting display device with improved color purity may be provided by preventing or reducing color mixing between pixels.

The effects that may be obtained from the present disclosure are not limited to the effects mentioned above, and other effects that are not mentioned may be clearly understood by those skilled in the art to which this disclosure belongs from the description above.

It is to be understood that both the foregoing general description and the following detailed description are by way of example and are intended to provide further explanation of the inventive concepts as claimed.

### BRIEF DESCRIPTION OF THE DRAWINGS

The accompanying drawings, which are included to provide a further understanding of the present disclosure and are incorporated in and constitute a part of this application, illustrate example embodiments of the disclosure and together with the description serve to explain the principles of the disclosure. In the drawings:

FIG. 1 is a diagram illustrating a schematic structure of a light emitting display device according to the present disclosure.

FIG. 2 is a circuit diagram illustrating a structure of one pixel included in the light emitting display device according to an example of the present disclosure.

FIG. 3 is a plan view illustrating an arrangement structure of the pixels disposed in the light emitting display device according to an example of the present disclosure.

FIG. 4 is an enlarged cross-sectional view along cutting line I-I′ in FIG. 3, for illustrating the structure of a light emitting display device according to an example of the present disclosure.

FIG. 5 is an enlarged cross-sectional view along cutting line II-II′ in FIG. 3, for illustrating light paths in a light emitting display device according to an example of the present disclosure.

FIG. 6 is an enlarged cross-sectional view, along line III-III′ in FIG. 3, illustrating light paths in a light emitting display device according to a first example embodiment of the present disclosure.

FIG. 7 is an enlarged cross-sectional view, along line III-III′ in FIG. 3, illustrating a structure of a light emitting display device according to a second example embodiment of the present disclosure.

FIG. 8 is an enlarged cross-sectional view, along line III-III′ in FIG. 3, illustrating a structure of a light emitting display device according to a third example embodiment of the present disclosure.

FIG. 9 is an enlarged cross-sectional view, along line III-III′ in FIG. 3, illustrating a structure of a light emitting display device according to the fourth example embodiment of the present disclosure.

FIG. 10 is an enlarged cross-sectional view, along line III-III′ in FIG. 3, illustrating a structure of a light emitting display device according to the fifth example embodiment of the present disclosure.

FIG. 11 is an enlarged plan view illustrating a structure of a light emitting display device according to a sixth example embodiment of the present disclosure.

### DETAILED DESCRIPTION

Advantages and features of the present disclosure, and implementation methods thereof will be clarified through following example embodiments described with reference to the accompanying drawings. The present disclosure may, however, be embodied in different forms and should not be construed as limited to the embodiments set forth herein. Rather, these example embodiments are provided so that this disclosure may be sufficiently thorough and complete to assist those skilled in the art to fully understand the scope of the present disclosure. Further, the protected scope of the present disclosure is defined by claims and their equivalents.

The shapes, sizes, ratios, angles, numbers, and the like, which are illustrated in the drawings to describe various example embodiments of the present disclosure, are merely given by way of example. Therefore, the present disclosure is not limited to the illustrated details. Like reference numerals refer to like elements throughout the specification unless otherwise specified. In the following description, where the detailed description of the relevant known function or configuration may unnecessarily obscure an important point of the present disclosure, a detailed description of such known function of configuration may be omitted.

Reference will now be made in detail to various embodiments of the present disclosure, examples of which are illustrated in the accompanying drawings. Wherever possible, the same reference numbers will be used throughout the drawings to refer to the same or like parts. In the specification, it should be noted that like reference numerals already used to denote like elements in other drawings are used for elements wherever possible. In the following description, when a function and a configuration known to those skilled in the art are irrelevant to the essential configuration of the present disclosure, their detailed descriptions will be omitted. The terms described in the specification should be understood as follows.

In the present specification, where the terms “comprise,” “have,” “include,” and the like are used, one or more other elements may be added unless a more limiting term, such as “only,” is used. An element described in the singular form is intended to include a plurality of elements, and vice versa, unless the context clearly indicates otherwise.

In construing an element, the element is construed as including an error or tolerance range even where no explicit description of such an error or tolerance range is provided.

In the description of the various embodiments of the present disclosure, where positional relationships are described, for example, where the positional relationship between two parts is described using “on,” “over,” “under,” “above,” “below,” “beside,” “next,” or the like, one or more other parts may be located between the two parts unless a more limiting term, such as “immediate(ly),” “direct(ly),” or “close(ly)” is used. For example, where an element or layer is disposed “on” another element or layer, a third layer or element may be interposed therebetween. Also, if a first element is described as positioned “on” a second element, it does not necessarily mean that the first element is positioned above the second element in the figure. The upper part and the lower part of an object concerned may be changed depending on the orientation of the object. Consequently, where a first element is described as positioned “on” a second element, the first element may be positioned “below” the second element or “above” the second element in the figure or in an actual configuration, depending on the orientation of the object.

In describing a temporal relationship, when the temporal order is described as, for example, “after,” “subsequent,” “next,” or “before,” a case which is not continuous may be included unless a more limiting term, such as “just,” “immediate(ly),” or “direct(ly),” is used.

It will be understood that, although the terms “first,” “second,” and the like may be used herein to describe various elements, these elements should not be limited by these terms as they are not used to define a particular order. These terms are used only to refer to one element separately from another. For example, a first element could be termed a second element, and, similarly, a second element could be termed a first element, without departing from the scope of the present disclosure.

In describing various elements in the present disclosure, terms such as first, second, A, B, (a), and (b) may be used. These terms are used merely to refer to one element separately from another, and not to define a particular nature, order, sequence, or number of the elements. Where an element is described as being “linked”, “coupled,” or “connected” to another element, that element may be directly or indirectly connected to that other element unless otherwise specified. It is to be understood that additional element or elements may be “interposed” between the two elements that are described as “linked,” “connected,” or “coupled” to each other.

It should be understood that the term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, and the third element.

Features of various embodiments of the present disclosure may be partially or overall coupled to or combined with each other, and may be variously inter-operated with each other and driven technically as those skilled in the art can sufficiently understand. The embodiments of the present disclosure may be carried out independently from each other, or may be carried out together in a co-dependent relationship.

Hereinafter, examples of a display apparatus according to the present disclosure will be described in detail with reference to the attached drawings. Wherever possible, the same reference numbers will be used throughout the drawings to refer to the same or like parts.

Hereinafter, with reference to figures, the present disclosure will be explained. FIG. 1 is a diagram illustrating a schematic structure of a light emitting display device according to the present disclosure. In FIG. 1, X-axis refers to the direction parallel to the scan line, Y-axis refers to the direction of the data line, and Z-axis refers to the height direction of the display device.

As shown in FIG. 1, the light emitting display device according to an example embodiment of the present disclosure comprises a substrate 110, a gate (or scan) driver 200, a pad portion 300, a source driving IC (Integrated Circuit) 410, a flexible circuit film 430, a circuit board 450, and a timing controller 500.

The substrate 110 may include an electrical insulating material or a flexible material. The substrate 110 may be made of a glass, a metal or a plastic, but it is not limited thereto. When the light emitting display device is a flexible display, the substrate 110 may be made of the flexible material such as plastic. For example, the substrate 110 may include a transparent polyimide material.

The substrate 110 may include a display area AA and a non-display area NDA. The display area AA, which is an area for representing the video images, may be defined as the majority middle area of the substrate 110, but it is not limited thereto. In the display area AA, a plurality of scan lines (or gate lines), a plurality of data lines and a plurality of unit pixels UP may be formed or disposed. The unit pixels UP are arrayed in a matrix manner. Each of unit pixels UP may include a plurality of pixels P. Each of pixels P includes the scan line and the data line, respectively.

The non-display area NDA, which is an area not representing the video images, may be defined at the circumference areas of the substrate 110 surrounding all or some of the display area AA. In the non-display area NDA, the gate driver 200 and the pad portion 300 may be formed or disposed.

The gate driver 200 may supply the scan (or gate) signals to the scan lines according to the gate control signal input through the pad portion 300 from the timing controller 500. The gate driver 200 may be formed at the non-display area NDA at any one outside of the display area AA on the substrate 110, as a GIP (Gate driver In Panel) type. GIP type means that the gate driver 200 is directly formed on the substrate 110. For example, the gate driver 200 may be configured as a shift resistor, and the GIP type refers to a structure in which transistors for the shift resistor of the gate driver 200 are directly formed on the substrate 110.

The pad portion 300 may supply data signals to data lines according to a data control signal input from the timing control unit 500. The pad portion 300 may be formed as a driving chip and mounted the flexible circuit film 430. The flexible circuit film 430 may be attached to the non-display area NDA of one edge of the display area AA of the substrate 110.

The source driving IC 410 may receive the digital video data and the source control signal from the timing controller 500. The source driving IC 410 may convert the digital video data into the analog data voltages according to the source control signal and then supply that to the data lines. When the source driving IC 410 is made as a chip type, it may be installed on the flexible circuit film 430 as a COF (chip on film) or COP (chip on plastic) type.

The flexible circuit film 430 may include a plurality of first link lines connecting the pad portion 300 to the source driving IC 410, and a plurality of second link lines connecting the pad portion 300 to the circuit board 450. The flexible circuit film 430 may be attached on the pad portion 300 using an anisotropic conducting film, so that the pad portion 300 may be connected to the first link lines of the flexible circuit film 430.

The circuit board 450 may be attached to the flexible circuit film 430. The circuit board 450 may include a plurality of circuits implemented as the driving chips. For example, the circuit board 450 may be a printed circuit board or a flexible printed circuit board. The circuit board 450 may be a printed circuit board or a flexible printed circuit board.

The timing controller 500 may receive the digital video data and the timing signal from an external system board through the line cables of the circuit board 450. The timing controller 500 may generate a gate control signal for controlling the operation timing of the gate driver 200 and a source control signal for controlling the source driving IC 410, based on the timing signal. The timing controller 500 may supply the gate control signal to the gate driver 200 and supply the source control signal to the source driving IC 410. Depending on the product types, the timing controller 500 may be formed as one chip with the source driving IC 410 and mounted on the substrate 110.

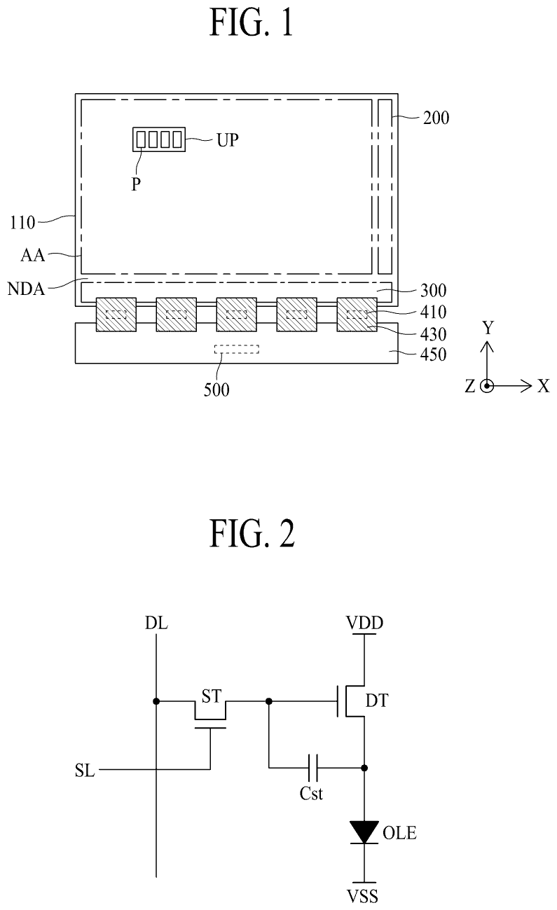

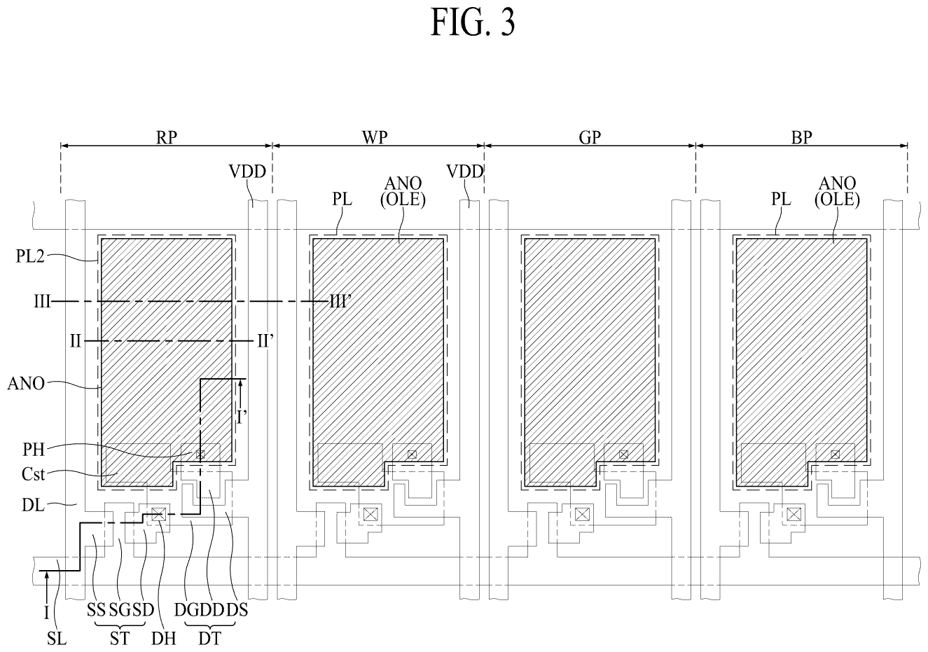

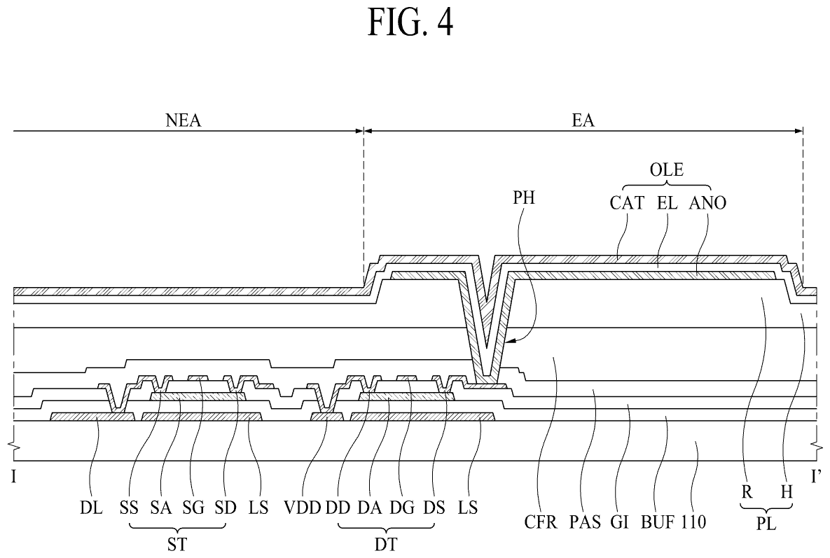

Hereinafter, with reference to FIGS. 2 to 4, an example embodiment of the present disclosure will be explained. FIG. 2 is a circuit diagram illustrating a structure of one pixel included in the light emitting display device according to an example of the present disclosure. FIG. 3 is a plan view illustrating an arrangement structure of the pixels disposed in the light emitting display device according to an example of the present disclosure. FIG. 4 is an enlarged cross-sectional view along cutting line I-I′ in FIG. 3, for illustrating the structure of a light emitting display device according to an example of the present disclosure.

As shown in FIGS. 2 to 4, a light emitting display device includes a plurality of unit pixels P in a matrix manner. Each unit pixel UP of the light emitting display may include three pixels P or four pixels P. For example, one unit pixel P may include a red pixel RP, a green pixel GP and a blue pixel BP. For another example, as shown in FIG. 3, one unit pixel UP may include one red pixel RP, a white pixel WP, a green pixel GP, and a blue pixel BP.

One pixel P of the light emitting display device, i.e., any one among red pixel RP, white pixel WP, green pixel GP and blue pixel BP, may be defined by a scan line SL, a data line DL and a driving current line VDD. In any one pixel of the light emitting display device may include a switching thin film transistor ST, a driving thin film transistor DT, a light emitting diode OLE, and a capacitance Cst. The driving current line VDD may be supplied with a high-level voltage for driving the light emitting diode OLE.

The cross-sectional structure of the light emitting display device, as shown in FIG. 4, may include a light shielding layer LS, a data line DL, and a driving current line VDD disposed on a substrate 110. The light shielding layer LS may be disposed as being overlapped with the semiconductor layers SA and DA. The light shielding layer LS may prevent external light from penetrating into the semiconductor layers SA and DA and changing the characteristics of the device. The data line DL and the driving current line VDD may be separated from the light shielding layer LS, and be lines extending from the upper side of the substrate 110 to the bottom side of the substrate 110 along Y-axis. FIG. 4 shows an example in which the data line DL and the driving current line VDD are formed on the same layer with the light shielding layer LS. However, it is not limited thereto, other signal line may further be disposed on the same layer. For example, a reference signal line may be further disposed at the same layer.

The switching thin film transistor ST may be disposed at a location where the scan line SL and the data line DL intersect. The switching thin film transistor ST may include a gate electrode SG, a semiconductor layer SA, a source electrode SS and a drain electrode SD. The gate electrode SG may be connected to the scan line SL. The source electrode SS may be connected to the data line DL, and the drain electrode SD may be connected to the driving thin film transistor DT. The semiconductor layer SA may be disposed on a gate insulating layer GI as overlapping with the gate electrode SG. The portion of the semiconductor layer SA overlapping the gate electrode SG may be defined as a channel region.

An intermediate insulating layer IL may be deposited on the semiconductor layer SA. The source electrode SS and the drain electrode SD may be formed on the intermediate insulating layer IL. The source electrode SS may be connected to one side of the semiconductor layer SA via one contact hole formed at the intermediate insulating layer IL. The drain electrode SD may be connected to another side of the semiconductor layer SA via another contact dhole formed at the intermediate insulating layer IL. The switching thin film transistor ST may select a pixel P to be driven by applying a data signal to the driving thin film transistor DT.

The driving thin film transistor DT may drive the light emitting diode OLE of the pixel selected by the switching thin film transistor ST. The driving thin film transistor DT may include a gate electrode DG, a semiconductor layer DA, a source electrode DS and a drain electrode DD. The gate electrode DG of the driving thin film transistor DT may be connected to the drain electrode Dd of the switching thin film transistor ST. For example, the gate electrode DG of the driving thin film transistor DT may be connected to the drain electrode DD of the switching thin film transistor ST via a drain contact hole DH penetrating the gate insulating layer GI covering the gate electrode DG. The drain electrode DD may be connected to the driving current line VDD, and the source electrode DS may be connected to an anode electrode ANO of the light emitting diode OLE. The capacitance Cst may be disposed between the gate electrode DG of the driving thin film transistor DT and the anode electrode ANO of the light emitting diode OLE.

The intermediate insulating layer IL may be deposited on the semiconductor layer DA. The source electrode DS and the drain electrode DD may be formed on the intermediate insulating layer IL. The source electrode DS may be connected to one side of the semiconductor layer DA via one contact hole formed at the intermediate insulating layer IL. The drain electrode DD may be connected to another side of the semiconductor layer DA via another contact hole formed at the intermediate insulating layer IL.

The driving thin film transistor DT may be disposed between the driving current line VDD and the light emitting diode OLE. The driving thin film transistor DT may control the amount of current flowing from the driving current line VDD to the light emitting diode OLE according to the magnitude of the voltage of the gate electrode DG connected to the drain electrode SD of the switching thin film transistor ST.

The light emitting diode OLE may include an anode electrode ANO, an emission layer EL and a cathode electrode CAT. The light emitting diode OLE may emit lights in response to an electric current controlled by the driving thin film transistor DT. In detail, since the amount of light emitted may be adjusted according to the current controlled by the driving thin film transistor DT, the brightness of the light emitting display device may be controlled. The anode electrode ANO of the light emitting diode OLE may be connected to the source electrode DS of the driving thin film transistor DT, and the cathode electrode CAT may be connected to a low voltage line VSS to which a low potential voltage is applied. The light emitting diode OLE may be driven by the difference between a low-potential voltage and a high-potential voltage controlled by a driving thin film transistor DT.

A passivation layer PAS is deposited on the surface of the substrate 110 having the thin film transistors ST and DT. The passivation layer PAS may include an inorganic material such as silicon oxide (SiOx) or silicon nitride (SiNx). A color filter CF may be formed on the passivation layer PAS. The color filter CF may be disposed on each pixel P. For example, the color filter may include a red color filter CFR disposed at the red pixel RP, a green color filter CFG disposed at the green pixel GP, and a blue color filter CFB disposed at the blue pixel BP. Color filter may not be disposed at the white pixel WP.

A planarization layer PL may be deposited on the color filter CF. The planarization layer PL may be a thin film for making the surface of the substrate 110 on which thin film transistors ST and DT are formed flat. To make even the height difference, the planarization layer PL may be formed of an organic material.

A pixel contact hole PH for exposing a portion of the source electrode DS of the driving thin film transistor DT may be formed as penetrating the passivation layer PAS, the color filter CF and the planarization layer PL. An anode electrode ANO may be formed on the planarization layer PL. The anode electrode ANO may be connected to the source electrode DS of the driving thin film transistor DT via the pixel contact hole PH.

The planarization layer PL may have a level difference. For example, the planarization layer PL may be patterned using an anode electrode ANO as a mask. As a result, the planarization layer PL may have a structure in which the planarization layer PL may protrude upward, and the anode electrode ANO is formed on the protruded planarization layer PL.

For another example, a first planarization layer may be deposited on the entire surface of the substrate 110, and a second planarization layer may be formed as having an island shape protruded on the first planarization layer. In this case, the anode electrode ANO may be formed on the second planarization layer.

The anode electrode ANO may have different material depending on the emission type of the light emitting diode OLE. For the bottom emission type in which the light emitting diode OLE emits to the substrate 110, the anode electrode ANO may be formed of a transparent conductive material. For the top emission type in which the light emitting diode OLE emits upward opposing the substrate 110, the anode electrode ANO may be formed of a metal material having excellent light reflectance. In this case, the anode electrode ANO may have a structure in which a transparent conductive layer and a metal layer are stacked.

For the bottom emission type, the anode electrode ANO may be made of a transparent conductive material (TCO) or semi-transparent conductive material. For instance, the anode electrode ANO may be made of a transparent conductive material such as indium tin oxide (ITO), indium zinc oxide (IZO) or indium zinc tin oxide (IZTO). Otherwise, the anode electrode ANO may be made of a semi-transparent layer of magnesium (Mg), silver (Ag) or an alloy of magnesium (Mg) and silver (Ag) with a thickness of less than 100 nm. The anode electrode ANO may be called as a first electrode or a transparent electrode.

An emission layer EL may be deposited on the anode electrode ANO. The emission layer EL may be disposed on the entire surface of the substrate 110 as one sheet type covering continuously the upper surface of the substrate 110. The emission layer EL may include various functional layers stacked each other. For example, the emission layer EL may include a hole functional layer, an organic emission layer, an electron functional layer. Each of the hole functional layer and the electron functional layer may be deposited on the substrate 110 as continuous sheet type. The organic emission layer may have a sheet shape between the hole functional layer and the electron functional layer. However, it is not limited thereto. The organic emission layer may be disposed as separated as corresponding to each emission area EA of each pixel P.

In addition, the emission layer EL may include two or more emission portions for emitting white color light. For example, the emission layer EL may have a tandem structure in which a first emission layer and a second emission layer are vertically stacked for emitting white color light by mixing a first color light and a second color light. However, it is not limited thereto, the vertically stacked emission portions may include three or four layers.

A cathode electrode CAT may deposited on the emission layer EL. The cathode electrode CAT may be disposed as a thin layer shape continuously spread on the entire surface of the substrate 110. The stacked structure of the anode electrode ANO, the emission layer EL and the cathode electrode CAT may configure the light emitting diode OLE.

The cathode electrode CAT may be made of a metal material having excellent light reflectance. For example, the cathode electrode CAT may be formed of a metal material with excellent light reflectance with a thickness of at least 2,000 Å to 3,000 Å (200 nm to 300 nm). Here, the metal material having excellent light reflectance may include aluminum (Al), magnesium (Mg), calcium (Ca), silver (Ag) or alloy of them (i.e., aluminum-magnesium alloy (AlMg)) For another example, the cathode electrode CAT may include thin metal layer having high reflectance such as stack of aluminum and titanium (Ti/Al/Ti), stack of aluminum and indium tin oxide (ITO/Al/ITO), silver alloy, or stack of silver alloy and indium tin oxide (ITO/Ag alloy/ITO). Here, silver alloy may be an alloy of silver (Ag), palladium (Pd) and copper (Cu). The cathode electrode CAT may be called as a second electrode, reflection electrode, or counter electrode.

The stacked structure of the anode electrode ANO, the emission layer EL and the cathode electrode CAT may configure the light emitting diode OLE. The light emitting display device according to the present disclosure may have a structure in which each of light emitting diode OLE is disposed on the planarization layer PL patterned with protruding island shape within the pixel P.

In detail, within each pixel P, a planarization layer PL is applied over the entire surface of the substrate 110, and has a protruding portion in the shape of an island with a certain thickness. The anode electrode ANO is formed on the upper surface of the protruding portion of the planarization layer PL. The emission layer EL may be deposited to cover the upper surface of the planarization layer PL having steps and the upper surface of the anode electrode ANO. The cathode electrode CAT may be also deposited with the same profile as the emission layer EL. As a result, the cathode electrode CAT may have a cap, ‘∩’ (inverted U) shape facing downward. Since the cathode electrode CAT may be made of a metal material with excellent light reflectance, the cathode electrode CAT may have a structure in which the cap shaped micro mirrors are formed along the protruding portion of the planarization layer PL.

In the case of the bottom emission type, there may be a disadvantage in that the area ratio of the aperture area to the pixel area may be relatively smaller than top emission type, due to the thin film transistor ST and DT, capacitance Cst and lines SL, DL and VDD. The light emitting display device according to the present disclosure may provide a structure equipped with a micro mirror so that light generated from the emission layer may be provided toward the substrate 110 placed underneath without loss even though the aperture area is small.

The area occupied by the light emitting diode OLE including the anode electrode ANO, the emission layer EL and the cathode electrode CAT may be defined as an emission area EA providing light. The surrounding area, the area where the emission layer EL and the cathode electrode CAT are deposited but the anode electrode ANO is not formed, may be defined as a non-emission area NEA where no light is emitted.

As shown in FIG. 4, in the case of having the micro mirrors, the emission layer EL and the cathode electrode CAT deposited on the inclined side of the protruding planarization layer PL may not configure the light emitting diode OLE. However, some of lights provided from the light emitting diode OLE may be reflected by the micro mirror and go out to the substate 110. Therefore, as the emission area EA shown in FIG. 4 may include micro mirror, the emission area EA may be larger than the area of the light emitting diode OLE.

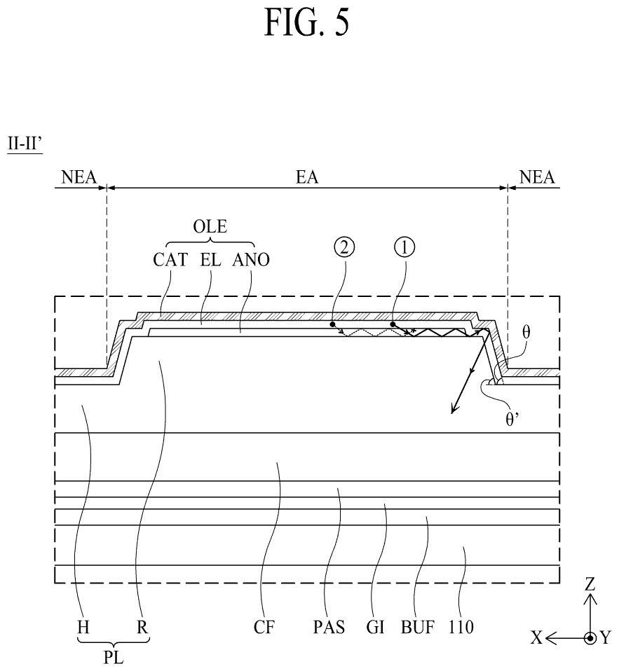

Hereinafter, with reference to FIG. 5, the mechanism for enhancing the light extraction efficiency by the micro mirror will be explained. FIG. 5 is an enlarged cross-sectional view along cutting line II-II′ in FIG. 3, for illustrating light paths in a light emitting display device according to an example of the present disclosure.

As shown in FIG. 5, it will be explained that the optical path \textcircled{1} for light emitted from the emission layer EL at the edge region of the anode electrode ANO. Lights emitted from the emission layer EL may be transmitted as a spherical wave. Lights may be emitted in all directions 360 degrees on the cross-sectional view. Among the lights, the light emitted to the top direction may be reflected by the cathode electrode CAT and travel downward. That is, most of all lights generated from the emission layer EL may be radiated in a 180-degree downward direction. These lights may be incident into the anode electrode ANO. Since the anode electrode ANO is made of a transparent conductive material, 60% to 70% of the lights may pass through the anode electrode ANO, pass through the color filter CF placed underneath, and be emitted outside the substate 110.

Further, the anode electrode ANO may be a transparent conductive material with a refractive index of 2.0 to 2.3. The upper surface of the anode electrode ANO is in contact with the emission layer EL, and the bottom surface is in contact with the planarization layer PL. The emission layer EL and the planarization layer PL may have a refractive index of 1.3 to 1.5. As a result, a structure may be formed in which an anode electrode ANO with a high refractive index is interposed between two low refractive layers. Therefore, among the lights incident into the anode electrode ANO, 30% to 40% corresponding to the total reflection condition may be propagated in the horizontal direction (X-axis direction) inside the anode electrode ANO.

According to the material of the emission layer EL, the refractive index of the emission layer EL may be similar to the refractive index of the anode electrode ANO. In this case, among the lights emitted from the emission layer EL, the lights totally reflected at the interface between the anode electrode ANO and the planarization layer PL may be trapped between the cathode electrode CAT and the planarization layer PL, so these lights may propagate in the horizontal direction (X-axis direction).

Lights propagating horizontally within the anode electrode ANO, or between the cathode electrode CAT and the planarization layer PL may be emitted from the end of the anode electrode ANO and be reflected by the cathode electrode CAT having the micro mirror structure to go downward. When there is no micro mirror structure formed by the protrusion of the planarization layer PL, the lights may be propagated horizontally and extinguished. However, according to this structure, the lights can be extracted downward by the micro mirror, thereby improving the light extraction efficiency.

Here, to ensure that the lights reflected by the cathode electrode CAT having a micro mirror structure may be emitted to the downward direction properly, the angle of the inclination of the cathode electrode CAT deposited on the etched side where the step of the planarization layer PL is formed may be adjusted. For example, the angle θ of the inclined surface of the cathode electrode CAT with respect to the horizontal surface of the substrate 110 may preferably be in the range of 40 degrees to 80 degrees. More preferably, the inclination angle θ may be in the range of 50 degrees to 75 degrees. Since the cathode electrode CAT is deposited along the step shape of the planarization layer PL, the inclination angle θ of the cathode electrode CAT may be substantially equal to the side wall inclination angle θ′ by the protrusion PR in the planarization layer PL. Therefore, it is preferable to form the inclination angle θ′ between the flat portion H and the protrusion portion R of the planarization layer PL to be 50 degrees to 75 degrees.

The light emitting display device according to the present disclosure may include the cathode electrode CAT having the micro mirror structure according to the shape of the planarization layer PL having a protrusion portion R extruded as an island from the flat portion H. Therefore, the light extraction efficiency may be improved by extracting the light that may be extinguished inside the anode electrode ANO among the lights generated from the emission layer EL.

Here, for convenience of explanation, based on one pixel, the planarization layer PL may be described as a structure in which a protrusion portion R is formed on the flat portion However, as considering the structure in which a large number of pixels are arranged in a matrix manner, the planarization layer PL may also be described as having a structure in which protrusion portions R and depression portions (corresponding to the flat portions H) are repeatedly arranged. That is, the flat portion H may be called a depression portion. In this case, the protrusion portions may correspond to the emission areas within each pixel, and the depressed portions may correspond to the non-emission areas surrounding the emission areas.

The light emitting display having the micro mirror structure described above may extract the lights that would otherwise be trapped and extinguished within the anode electrode ANO to the outside of the anode electrode ANO. However, the lights emitted from the emission layer EL at the central region of the anode electrode ANO may not be extracted to the outside.

Hereinafter, it is explained about the optical path \textcircled{2} for light emitted from the emission layer EL at the central region of the anode electrode ANO. Lights generated from the emission layer EL may be radiated 180 degrees downward by the same mechanism as described above. Since the anode electrode ANO is made of a transparent conductive material, 60% to 70% of the lights may pass through the anode electrode ANO, pass through the color filter CF placed underneath, and then be emitted outside the substrate 110.

However, among the lights incident into the anode electrode ANO, 30% to 40% that meet the total reflection condition may be propagated in the horizontal direction (X-axis direction) inside the anode electrode ANO. In particular, the lights generated at the central region of the pixel may undergo a total reflection process inside the anode electrode ANO, so that the length of the propagating optical path \textcircled{2} is longer than the length of the optical path \textcircled{1} described above. Therefore, it may be dissipated as heat energy inside the anode electrode ANO before being emitted through the end of the anode electrode ANO. In general, when lights propagate over a length of 20 μm or more inside the anode electrode ANO, the lights may be extinguished or annihilated.

In the following explanation, the description for driving element layer which is a common element will not be duplicated. Further, the configuration of the driving element layer is not limited to the explanation mentioned with reference to FIGS. 2 to 4. The configuration of the thin film transistors ST and DT may have any one structure of top gate structure, bottom gate structure and double gate structure. The thin film transistors ST and DT may include oxide semiconductor material. For example, the material for the semiconductor layers SA and DA may include a metal oxide material such as indium gallium zinc oxide (IGZO). However, it is not limited thereto, the semiconductor layers SA and DA may include any one of an amorphous silicon (a-Si), a polycrystalline silicon (Poly Si), or a low temperature polycrystalline silicon (LTPS).

In addition, the arrangement of the signal lines including scan line SL, data line DL and driving current line VDD may be varied. Other signal lines including reference line may be further included. In the following description, drawing numeric symbols which are shown in the drawings but not explained may be referred to the description of the drawing numeric symbols in FIGS. 2 to 4.

### First Example Embodiment

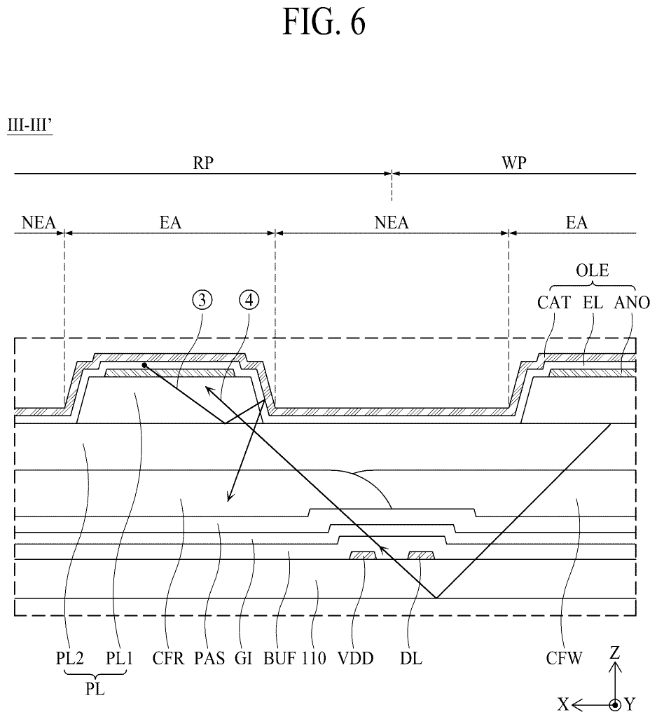

To prevent the light traveling horizontally by total reflection in the center of the anode electrode ANO from being dissipated into heat energy before reaching the end of the anode electrode ANO, as a structural improvement that prevents total reflection between the anode electrode ANO and the planarization layer PL, the first embodiment of the present disclosure provides a structure as shown in FIG. 6. FIG. 6 is an enlarged cross-sectional view, along line III-III′ in FIG. 3, illustrating light paths in a light emitting display device according to a first embodiment of the present disclosure.

As shown in FIG. 6, a light emitting display device according to a first embodiment of the present disclosure may have same structure as that of the light display device mentioned above. The different feature of the first embodiment is that the planarization layer PL includes a first planarization layer PL1 and a second planarization layer PL2 stacked each other.

The light emitting display device according to the first embodiment of the present disclosure comprises a planarization layer PL including a first planarization layer PL1 and a second planarization layer PL2 stacked on the first planarization layer PL1. The first planarization layer PL1 may be made of an organic material with a refractive index of 1.5. On the contrary, the second planarization layer PL2 may be made of a transparent organic material with a refractive index that is the same as or 0.2 lower than that of the anode electrode ANO.

The first planarization layer PL1 may have a certain thickness and be deposited to cover the entire surface of the substrate 110 having the color filter CF. The second planarization layer PL2 may be formed only in the area corresponding to the emission area EA on the first planarization layer PL1. That is, the first planarization layer PL1 may correspond to the flat portion H shown in FIG. 5, and the second planarization layer PL2 may correspond to the protrusion portion R.

The lights generated from the emission layer EL may radiate in the same way as the optical path \textcircled{3}. The lights generated from the emission layer EL may be radiated downwards 180 degree by the same mechanism described above. Since the anode electrode ANO is made of a transparent conductive material and the second planarization layer PL2 has a refractive index similar to that of the anode electrode ANO, 90% to 98% of lights may transmit through the anode electrode ANO and the second planarization layer PL2. Lights transmitted through the second planarization layer PL2 may be incident into the first planarization layer PL1. Since the first planarization layer PL1 has a refractive index of 1.4 to 1.5, 60% to 70% of the light incident into the second planarization layer PL2 may pass through the first planarization layer PL1, pass through the color filter CF arranged underneath, and go to the outside of the substrate 110.

However, among the lights incident into the second planarization layer PL2, 30% to 40% that satisfies the total reflection condition at the interface with the first planarization layer PL1 may be re-incident into the anode electrode ANO and then be totally reflected again from the upper surface of the anode electrode ANO. That is, these lights may propagate horizontally (X-axis direction) inside space of the anode electrode ANO and the second planarization layer PL2.

Unlike optical paths \textcircled{1} and \textcircled{2}, the space for total reflection may be expanded and the number of total reflection is significantly reduced due to the second planarization layer PL2 having a thickness of 1.0 μm to 1.5 μm. As a result, the light emitted from the central region of the pixel and totally reflected may also be reflected by the cathode electrode CAT having a micro mirror structure and go outside downward direction.

According to the light emitting display device according to the present disclosure, the light extraction efficiency may be improved by extracting lights generated from the emission layer EL due to the second planarization layer PL2 protruded in the shape of an island and the cathode electrode CAT having a micro mirror structure formed by the second planarization layer PL2. Furthermore, the second planarization layer PL2 may have a refractive index that is the same as or slightly lower than that of the anode electrode ANO, and the first planarization layer PL1 disposed under the second planarization layer PL2 may be configured to have a low refractive index. Therefore, the lights that would otherwise be lost due to total reflection may be extracted outside. Accordingly, the light extraction efficiency may be enhanced.

For example, the anode electrode ANO may have the refractive index in range of 2.0˜2.3. The second planarization layer PL2 may have the refractive index in range of 1.8˜2.0, which is the same as or 0.2 different from that of the anode electrode ANO. Meanwhile, the first planarization layer PL1 may have a refractive index in range of 1.3˜1.5 which is 0.5 or more lower than that of the second planarization layer PL2.

The light emitting display device according to the first embodiment may have a characteristic in which the amount of lights totally reflected at the interface between the anode electrode ANO and the second planarization layer PL2 may be minimized or reduced. As a result, almost all lights generated from the emission layer EL may pass through the second planarization layer PL2 so that the light extraction efficiency may be maximized or enhanced. In addition, lights which are totally reflected between the second planarization layer PL2 and the color filter CF may be reflected by the mirror structure and then go toward the substrate 110.

In FIG. 6, an area including a micro mirror formed by a light emitting diode OLE and a protruded second planarization layer PL2 may be defined as an emission area EA. The region where only the first planarization layer PL1 is placed without the second planarization layer PL2 between the emission areas EA may be defined as a non-emission area NEA.

The lights from the light emitting diodes OLE to the substrate 100 may be extracted by passing through the substrate 110. However, the outermost surface of the substrate 110 is in contact with air having a refractive index of 1.0. Therefore, some of the lights may be totally reflected at the outermost surface of the substrate 110. The lights which do not pass through the substrate 110 and are totally reflected may travel to neighboring pixels. As the result, color mixing may be occurred.

For example, the data line DL and the driving current line VDD may have a plan layer structure parallel to the top surface of the substrate 110 between the red pixel RP and the white pixel WP. Therefore, as shown in arrow mark \textcircled{4}, a portion of the lights emitted from the white pixel WP may be totally reflected on the top surface of the substrate 110 and then travel to the red pixel RP through the space between the driving current line VDD and the data line DL. That is, some lights emitted from the emission area EA of the white pixel WP may be totally reflected at the interface between the first planarization layer PL1 and the second planarization layer PL2 or at the bottom surface of the planarization layer PL, and then propagate to the neighboring red pixel RP through the non-emission area NEA. Lights propagated from the white pixel WP may be reflected by the cathode electrode of the red pixel RP and then go out through the emission area EA of the red pixel RP. Accordingly, the color purity or brightness of the red pixel RP may be changed, and the overall image quality may be distorted.

The above color mixing problem may not only occur between the red pixel RP and the white pixel WP, but may also occur between the red pixel RP and the blue pixel BP, between the white pixel WP and the green pixel GP, and between the green pixel GP and the blue pixel BP. Further, it is not limited thereto, lights generated from the green pixel GP may also affect to the red pixel RP depending on the total reflection conditions.

The color mixing phenomenon may lower the color purity of the light emitting display device, which may adversely affect to the display quality. In the following embodiments, structures are further proposed that may prevent or reduce color mixing problem due to lights which may be totally reflected but not penetrate the substrate 110.

### Second Example Embodiment

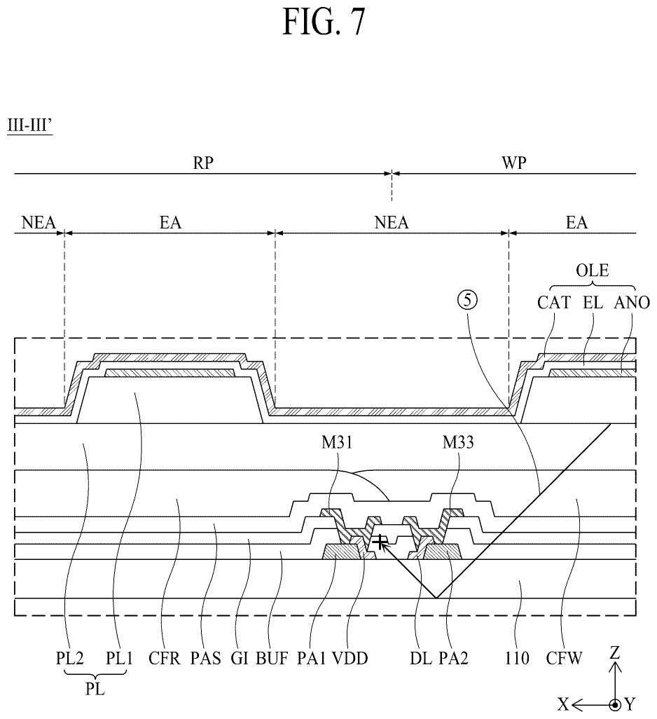

Hereinafter, with reference to FIG. 7, a structure of a light emitting display device according to the second embodiment of the present disclosure will be explained. FIG. 7 is an enlarged cross-sectional view, along line III-III′ in FIG. 3, illustrating a structure of a light emitting display device according to a second embodiment of the present disclosure.

As shown in FIG. 7, a light emitting display device according to the second embodiment may have very similar structure with that of the first embodiment. The different feature is on a structure of the signal lines disposed between pixels. For example, the data line DL and the driving current line VDD shown in FIG. 6 may have a flat thin film parallel to the surface of the substrate 110 between the red pixel RP and the white pixel WP. On the contrary, in the second embodiment as shown in FIG. 7, the driving current line VDD and the data line DL may have certain inclined angle toward the vertical direction with respect to the surface of the substrate 110.

For an example, in the non-emission area NEA between the red pixel RP and the white pixel WP, a first pattern PA1 and a second pattern PA2 may be disposed. The first pattern PA1 and the second pattern PA2 may be made of an inorganic insulating material or an organic insulating material. For example, they may be made of silicon oxide or silicon nitride. The first pattern PA1 and the second pattern PA2 may have a long line segment shape extending from the upper side to the lower side on the plan surface of the substrate 110. The first pattern PA1 and the second pattern PA2 may preferably have the shape with a relatively thicker height than width or relatively narrow width than the height. The first pattern PA1 may be disposed adjacent to the red pixel RP and the second pattern PA2 may be disposed adjacent to the white pixel WP.

The driving current line VDD for the red pixel RP may be disposed at one side of the first pattern PA1. In detail, the driving current line VDD of the red pixel RP may contact the right upper surface of the first pattern PA1 and right sidewall of the first pattern PA1, as shown in FIG. 7. The data line DL of the white pixel WP may be disposed at on side of the second pattern PA2. In detail, the data line DL of the white pixel WP may contact the left upper surface of the second pattern PA2 and the left sidewall of the second pattern PA2. Further, even though it is not shown in FIG. 7, the data line DL of the red pixel RP may be disposed at the left side of the red pixel RP, and may be disposed at one side of the second pattern PA2.

The driving current line VDD for the red pixel RP, due to the height of the first pattern PA1 may be arranged in a shape inclined at certain angle toward the vertical direction with respect to the surface of the substrate 110.

The driving current line VDD and the data line DL may be made of portions of the light shielding layer LS. The buffer layer BUF and the gate insulating layer GI may be deposited on the driving current line VDD and the data lien DL. Further, by patterning the buffer layer BUF and the gate insulating layer GI, some of the driving current line VDD and the data line DL may be exposed.

A first auxiliary line M31 and the second auxiliary line M32 may be formed on the gate insulating layer as being contact with the driving current line and the data line DL, respectively. For example, the first auxiliary line M31 and the second auxiliary line M33 may be in contact with the driving current line VDD and the data line DL, respectively, via contact holes penetrate the gate insulating layer GI and the buffer layer BUF. The first auxiliary line M31 and the second auxiliary line M33 may be made as forming the gate electrodes SG and DG, source electrode SS and DS and drain electrode SD and DD, as shown in FIG. 4. However, it is not limited thereto, the first auxiliary line M31 and the second auxiliary line M33 may be made of a third metal layer different from the electrodes SG, DG, SS, DS, SD and DD. The first auxiliary line M31 and the second auxiliary line M33 may be also arranged in a shape inclined at certain angle in the vertical direction with respect to the surface of the substrate 110, due to the step (or level) difference between the buffer layer BUF and the gate insulating layer GI.

The first auxiliary line M31 and the second auxiliary line M33 may be in contact with the driving current line VDD and the data line DL, respectively, as running along Y-axis on the surface of the substrate 110. In this case, the first auxiliary line M31 and the second auxiliary line M33 should not be in contact with the lines running along X-axis on the surface of the substrate 110. Therefore, the first auxiliary line M31 and the second auxiliary line M33 may have a short line segment shape having a length corresponding to the length of one side of the emission area in a pixel. For example, the first auxiliary line M31 and the second auxiliary line M33 may be configured to contact the driving current line VDD and the data line DL, respectively, in a line segment shape corresponding to the length from the upper side to the lower side of the anode electrode ANO indicated by hatching in FIG. 3.

In addition, for the case in which the first auxiliary line M31 and the second auxiliary line M33 are made of third metal layer, they may be formed on the passivation layer PAS. In this case, the first auxiliary line M31 and the second auxiliary line M33 may be in contact with the driving current line VDD and the data line DL, respectively, via contact holes penetrate the passivation layer PAS, the gate insulating layer GI and the buffer layer BUF. Since the step of the contact hole may be deeper, the first auxiliary line M31 and the second auxiliary line M33 may be formed with an inclined angle closer to vertical.

The passivation layer PAS may be deposited on the first auxiliary line M31 and the second auxiliary line M33. A color filter may be formed on the passivation layer PAS. For example, a red color filter CFR may be disposed at the red pixel RP, and a white color filter CFW may be disposed at the white pixel WP. The white color filter CFW may be omitted or be made of a transparent organic material.

A first planarization layer PL1 may be deposited on the color filter as covering entire surface of the substrate 110. A second planarization layer PL2 may be formed on the first planarization layer PL1 corresponding to the emission area EA. The second planarization layer PL2 may have a shape that protrudes over the first planarization layer PL1 with a predetermined height.

An anode electrode ANO may be formed on the second planarization layer PL2. An emission layer EL may be deposited on the anode electrode ANO, the first planarization layer PL1 and the second planarization layer PL2. A cathode electrode CAT may be deposited on the emission layer EL.

Due to the shape of the second planarization layer PL2, the cathode electrode CAT may have a convex mirror shape in the upward direction, line an ‘n’ shape. That is, a mirror structure is formed surrounding the anode electrode ANO.

Most of the lights provided from the emission layer EL may pass through the second planarization layer PL2. However, some of the light may be reflected at the interface with the first planarization layer PL1 by total reflection phenomena. The reflected light may be reflected again by the cathode electrode CAT and then go toward substrate 110.

Among the lights emitted from the pixels, some may become leakage lights (\textcircled{5}), as indicated by the arrows in FIG. 7, and may be reflected again on the bottom surface of the substrate 110 and then may be re-enter to neighboring pixels. According to the second embodiment, the driving current line VDD, the data line DL, the first auxiliary line M31 and the second auxiliary line M33 may have certain inclined angles with respect to the vertical direction. Therefore, the light re-entering into the pixel from the neighboring pixels may be blocked by the driving current line VDD, the data line DL, the first auxiliary line M31 and the second auxiliary line M33.

The light emitting display device according to the second embodiment may have a structure for preventing or mitigating the light leakage problem, by forming light blocking layers having inclined angle to the vertical direction with respect to the plan surface of the substrate 110 at the non-emission area NEA between neighboring two pixels. Here, the light blocking layers may include a first layer and a second layer stacked each other. The first layer may be made at the same layer as the light shielding layer LS that prevents lights from entering into the semiconductor layer SA and DA. The second layer may be line for supplying signal to the thin film transistors ST and DT. In the second embodiment, the first layer may include the data line DL and the driving current line VDD formed at the same layer as the light shielding layer LS. The second layer may include the first auxiliary line M31 and the second auxiliary line M33 made of the metal material used for the gate electrodes SG and DG.

As a result, the lights emitted from a pixel may be prevented from re-entering into the neighboring pixel by being reflected on the lower surface of the substrate. Thereby, the color mixing problem may be prevented or mitigated. Accordingly, the light emitting display device according to the second embodiment of the present disclosure may provide high quality picture and video images with improved color purity as well as enhanced light extraction efficiency.

### Third Example Embodiment

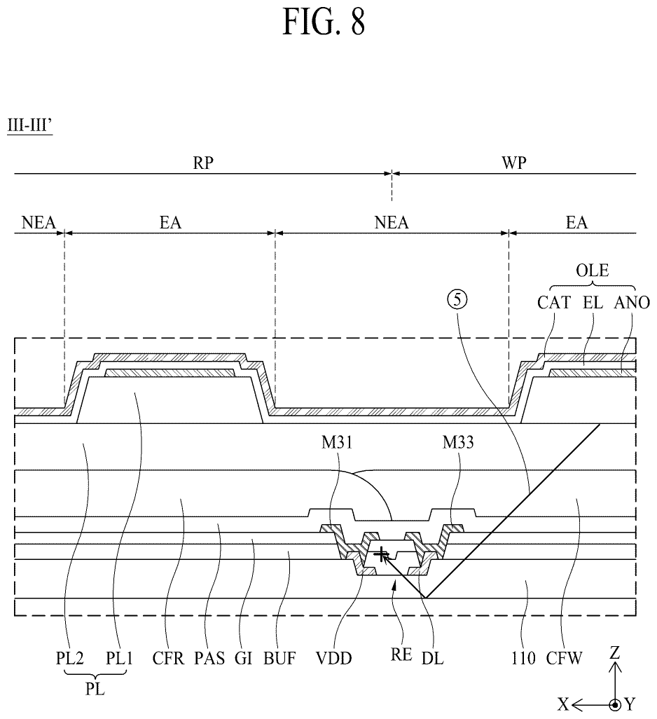

Hereinafter, with reference to FIG. 8, a light emitting display device according to the third embodiment of the present disclosure will be explained. FIG. 8 is an enlarged cross-sectional view, along line III-III′ in FIG. 3, illustrating a structure of a light emitting display device according to a third embodiment of the present disclosure.

The light emitting display device according to the third embodiment of the present disclosure, as shown in FIG. 8, may have a very similar structure to that of the second embodiment. The third embodiment may have an structural feature in which a recessed portion may be formed by etching portions of the substrate 110 to make lines have an inclined shape in the vertical direction so lights entering into a pixel from neighboring pixels may be blocked.

As shown in FIG. 8, a trench RE having well shape may be formed at the non-emission area NEA where the signal lines are disposed between pixels on the substrate 110. For example, a trench RE having lone line segment shape from upper side to lower side of the substate 110 may be formed between each of pixel columns.

The trench RE may have a vessel shape in which two etched walls face each other, and a bottom face is connecting bottom sides of these two side walls, in the cross-sectional view. For example, a trench RE may be formed along Y-axis on the surface of the substrate 110 between the red pixel RP and the white pixel WP. One etched side wall of the trench RE may be closed to the red pixel RP, and the other etched side wall of the trench TR may be closed to the white pixel WP.

The driving current line VDD of the red pixel RP may be disposed at one etched side wall of the trench RE closed to the red pixel RP. Further, the data line DL of the white pixel WP may be disposed at the other side wall of the trench RE closed to the white pixel WP.

The driving current line VDD of the red pixel RP may be arranged at certain inclined angle with respect to the vertical direction with respect to the surface of the substrate 110, due to the depth of the trench RE. Further, the data line DL of the white pixel WP may be arranged at certain inclined angle with respect to the vertical direction with respect to the surface of the substrate 110.

The driving current line VDD and the data line DL may be formed of the same material as the light shielding layer LS. The buffer layer BUF and the gate insulating layer GI may be sequentially stacked on the driving current line VDD and the data line DL. After patterning the buffer layer BUF and the gate insulating layer GI, some portions of the driving current line VDD and the data line DL may be exposed.

The first auxiliary line M31 and the second auxiliary line M33 may be formed as being contact with exposed portions of the driving current line VDD and the data line DL, respectively, on the gate insulating layer GI. Due to the step differences of the buffer layer BUF and the gate insulating layer GI, the first auxiliary line M31 and the second auxiliary line M33 may be arranged at certain inclined angle with respect to the vertical direction with respect to the surface of the substrate 110.

The first auxiliary line M31 and the second auxiliary line M33 may be in contact with the driving current line VDD and the data line DL, respectively, which are running along Y-axis on the surface of the substrate 110. The first auxiliary line M31 and the second auxiliary line M22 may have short line segment shape corresponding to the emission area EA in the pixel area. For example, the first auxiliary line M31 and the second auxiliary line M33 may be configured to contact the driving current line VDD and the data line DL, respectively, with a line segment shape corresponding to the length from the upper side to the lower side of the anode electrode ANO indicated by hatching in FIG. 3.

A passivation layer PAS may be deposited on the first auxiliary line M31 and the second auxiliary line M33. A color filter may be deposited on the passivation layer PAS. For example, a red color filter CFR may be disposed in the red pixel RP, and a white color filter CFW may be disposed in the white pixel WP. The white color filter CFW may be omitted, or may be made of a transparent organic material. When the white color filter CFW is omitted, the first planarization PL1 made of a transparent organic material and stacked on the other color filters may be the white color filter CFW.

The first planarization layer PL1 may be deposited on the color filter as covering entire surface of the substrate 110. A second planarization layer PL2 may be deposited on the first planarization layer PL1 corresponding to the emission area.

An anode electrode ANO may be formed on the second planarization layer PL2. An emission layer EL may be deposited on the anode electrode ANO, the first planarization layer PL1 and the second planarization layer PL2. A cathode electrode CAT may be deposited on the emission layer EL.

Most of the lights provided from the emission layer EL may pass through the second planarization layer PL2. However, some of the light may be reflected at the interface with the first planarization layer PL1 by total reflection phenomena. The reflected light may be reflected again by the cathode electrode CAT and then go toward substrate 110.

Among the lights emitted from the pixels, some may become leakage lights (\textcircled{5}), as indicated by the arrows in FIG. 8, and may be reflected again on the bottom surface of the substrate 110 and then may be re-enter to neighboring pixels. However, the light re-entering into the pixel from the neighboring pixels may be blocked by the driving current line VDD, the data line DL, the first auxiliary line M31 and the second auxiliary line M33.

As a result, the lights emitted from a pixel may be prevented from re-entering into the neighboring pixel by being reflected on the lower surface of the substrate. Thereby, the color mixing problem may be prevented or mitigated. Accordingly, the light emitting display device according to the third embodiment of the present disclosure may provide high quality picture and video images with improved color purity as well as enhanced light extraction efficiency.

The light emitting display device according to the second embodiment may have a structure for preventing or mitigating the light leakage problem, by forming light blocking layers having inclined angle to the vertical direction with respect to the plan surface of the substrate 110 at the non-emission area NEA between neighboring two pixels. Here, the light blocking layers may include a first layer and a second layer stacked each other. The first layer may be made at the same layer as the light shielding layer LS that prevents lights from entering into the semiconductor layer SA and DA. The second layer may be line for supplying signal to the thin film transistors ST and DT. In particular, by forming the trench RE recessing some of the substate 110, the first layer may have an inclined angle closed to the vertical line to the surface of the substrate 110.

### Fourth Example Embodiment

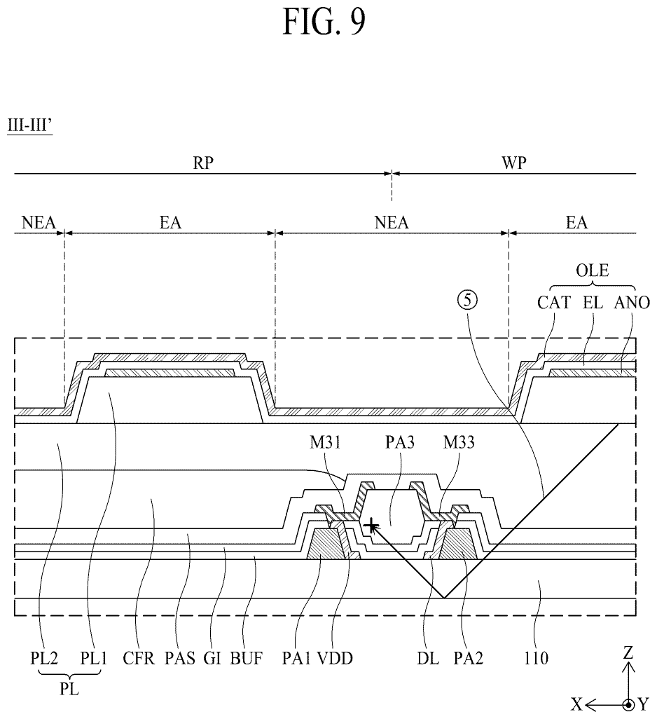

Hereinafter, with reference to FIG. 9, a light emitting display device according to the fourth embodiment of the present disclosure will be explained. FIG. 9 is an enlarged cross-sectional view, along line III-III′ in FIG. 3, illustrating a structure of a light emitting display device according to the fourth embodiment of the present disclosure.

The structure of a light emitting display device according to the fourth embodiment of the present disclosure as shown in FIG. 9 may have a very similar structure as the second embodiment. The different feature is on the structure of the light blocking layer. Therefore, following description may be focused on this different feature.

A first pattern PA1 and a second pattern PA2 may be formed at the non-emission area NEA on a substrate 110. The first pattern PA1 and the second pattern PA2 may be made of an inorganic material or an organic material. In the fourth embodiment, the light blocking layer may be configured to have a slop that is nearly perpendicular to the surface of the substrate 110. Therefore, the first pattern PA1 and the second pattern PA2 may be much thicker than those of the second embodiment.

A driving current line VDD may be formed at one side of the first pattern PA1. A data line DL may be formed at one side of the second pattern PA2. Since the first pattern PA1 and the second pattern PA2 may be thicker than those of the second embodiment, the driving current line VDD and the data line DL may be formed with inclined angles near to vertical direction.

A buffer layer BUF and a gate insulating layer GI may be deposited on the driving current line VDD and the data line DL. By removing some of the buffer layer BUF and the gate insulating layer GI, some of top surfaces of the driving current line VDD and the data line DL may be exposed.

A third pattern PA3 may be formed on the gate insulating layer GI between the driving current line VDD and the data line DL. The third pattern PA3 may have a thickness the same as the thickness of the first pattern PA1 and the second pattern PA2. A first auxiliary line M31 and a second auxiliary line M33 may be formed on the gate insulating layer and the third pattern PA3.

The first auxiliary line M31 may be formed across one side of the third pattern PA3 while being connected to the driving current line VDD. The second auxiliary line M33 may be formed across the other side of the third pattern PA3 while being connected to the data line DL. Since the third pattern PA3 may be thick, the first auxiliary line M31 and the second auxiliary line M33 may be formed with an inclined angle close to vertical direction.

A passivation layer PAS may be deposited on the substrate 110 having the first auxiliary line M31 and the second auxiliary line M33. A color filter may be formed on the passivation layer PAS. A red color filter CFR may be formed in the red pixel RP. However, there may be no color filter in the white pixel WP. Even it is not shown in figures, a green color filter may be formed in the green pixel, and a blue color filter may be formed in the blue pixel.

The stacked structure after the color filter may be same as described in the second embodiment. With this condition, some leakage lights \textcircled{5} among the lights emitted from the white pixel WP may enter into the red pixel RP. However, the leakage lights \textcircled{5} may be blocked by the first light blocking layer formed of the driving current line VDD and the first auxiliary line M31, and/or second light blocking layer formed of the data line DL and the second auxiliary line M33.

The light emitting display device according to the second embodiment may have a structure for preventing or mitigating the light leakage problem, by forming light blocking layers having inclined angle to the vertical direction with respect to the plan surface of the substrate 110 at the non-emission area NEA between neighboring two pixels. Here, the light blocking layers may include a first layer and a second layer stacked each other. The first layer may be made at the same layer as the light shielding layer LS that prevents lights from entering into the semiconductor layer SA and DA. The second layer may be line for supplying signal to the thin film transistors ST and DT. In particular, the third pattern layer PA3 may be formed on the first layer, and the second layer may be formed thereon. Therefore, the second layer may have an inclined angle closed to the vertical line to the surface of the substrate 110. As a result, it may more reliably block the lights leaked between neighboring pixels.

### Fifth Example Embodiment

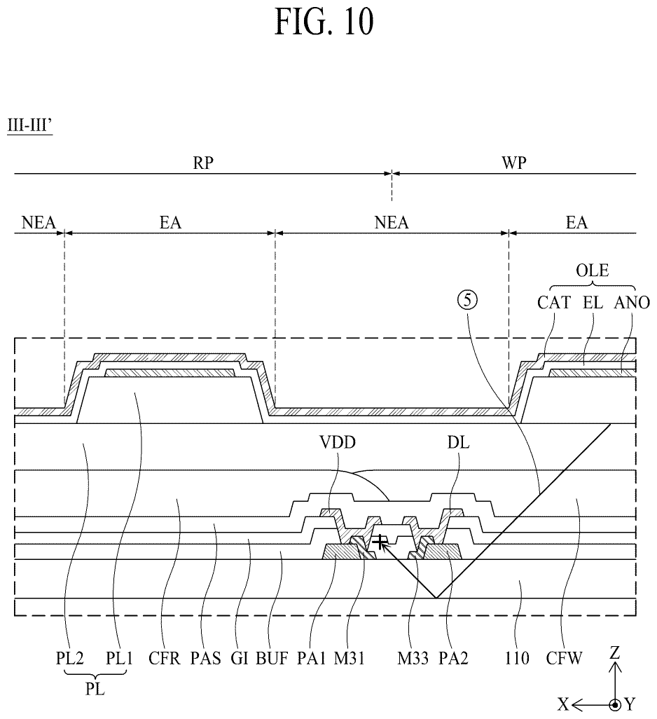

Hereinafter, with reference to FIG. 10, a light emitting display device according to the fifth embodiment of the present disclosure will be explained. FIG. 10 is an enlarged cross-sectional view, along line III-III′ in FIG. 3, illustrating a structure of a light emitting display device according to the fifth embodiment of the present disclosure.

The structure of a light emitting display device according to the fifth embodiment of the present disclosure as shown in FIG. 10 may have a very similar structure as the second embodiment. The different feature is on the structure of the light blocking layer. Therefore, following description may be focused on this different feature.

A first pattern PA1 and a second pattern PA2 may be formed at the non-emission area NEA on a substrate 110. The first pattern PA1 and the second pattern PA2 may be made of an inorganic material or an organic material. In the fifth embodiment, the light blocking layer may be configured to have a slop that is nearly perpendicular to the surface of the substrate 110.

A first auxiliary line M31 may be formed at one side of the first pattern PA1. A second auxiliary line M33 may be formed at one side of the second pattern PA2. Due to the thicknesses of the first pattern PA1 and the second pattern PA2, the first auxiliary line M31 and the second auxiliary line M33 may be formed with inclined angles.

A buffer layer BUF and a gate insulating layer GI may be deposited on the first auxiliary line M31 and the second auxiliary line M33. By removing some of the buffer layer BUF and the gate insulating layer GI, some of top surface of the first auxiliary line M31 and the second auxiliary line M33 may be exposed.

A driving current line VDD and a data line DL may be formed on the gate insulating layer GI. The driving current line VDD may be in contact with the first auxiliary line. The data line DL may be in contact with the second auxiliary line M33.

The structure above the driving current line VDD and the data line DL may be same with that of the second embodiment as shown in FIG. 7. With this condition, some leakage lights \textcircled{5} among the lights emitted from the white pixel WP may enter into the red pixel RP. However, the leakage lights \textcircled{5} may be blocked by the first light blocking layer formed of the first auxiliary line M31 and the driving current line VDD, and/or second light blocking layer formed of the second auxiliary line M33 and the data line DL.

The light emitting display device according to the second embodiment may have a structure for preventing or mitigating the light leakage problem, by forming light blocking layers having inclined angle to the vertical direction with respect to the plan surface of the substrate 110 at the non-emission area NEA between neighboring two pixels. Here, the light blocking layers may include a first layer and a second layer stacked each other. The first layer may be made at the same layer as the light shielding layer LS that prevents lights from entering into the semiconductor layer SA and DA. The first auxiliary line M31 and the second auxiliary line M33 may be metal layers by which any signals are not supplied. The second layer may be used for supplying signals to the thin film transistors ST and DT. In the fifth embodiment, the first layer may be disposed on the same layer with the light shielding layer LS, and may be formed as a metal layer having short segment shape corresponding to one side of the pixel and including the first auxiliary line M31 and the second auxiliary line M33. The second layer may be configured to include the driving current line VDD and the data line DL made of the metal material used for forming the source electrodes SS and DS and the drain electrodes SD and DD of the thin film transistors ST and DT.

### Sixth Example Embodiment

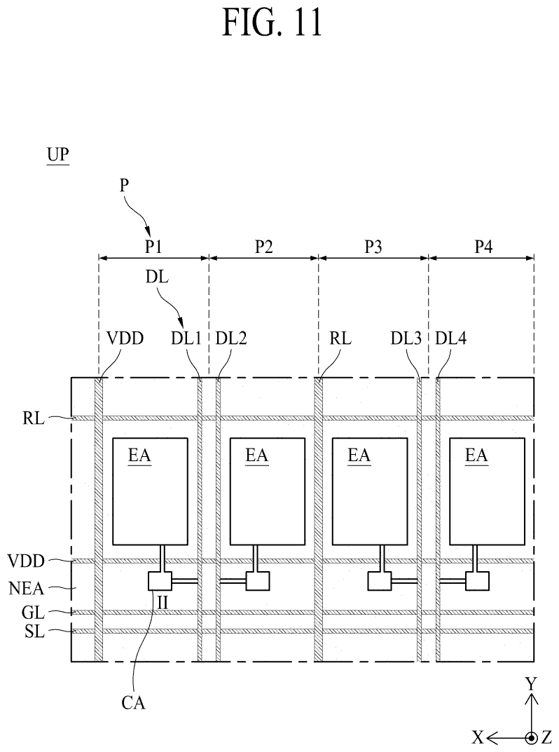

Hereinafter, with reference to FIG. 11, a light emitting display device according to the sixth embodiment of the present disclosure will be explained. FIG. 11 is an enlarged plan view illustrating a structure of a light emitting display device according to a sixth embodiment of the present disclosure.

As shown in FIG. 11, a light emitting display device according to the sixth embodiment of the present disclosure may include one unit pixel UP having four pixels P. For example, one unit pixel UP may include a first pixel P1, a second pixel P2, a third pixel P3 and a fourth pixel P4. Here, the first pixel P1 may correspond to the red pixel, the second pixel P2 may correspond to the white pixel, the third pixel P3 may correspond to the green pixel, and the fourth pixel P4 may correspond to the blue pixel.

Each pixel P may include an emission area EA and a non-emission area NEA. In the non-emission area NEA, a driving element area CA and various lines. The various lines may include a driving current line VDD, data lines DL1, DL2, DL3 and DL4, a reference line RL, a gate line GL and a signal line SL.

The driving current line VDD may be disposed at the left side of the first pixel P1, and the first data line DL1 at the right side of the first pixel P1. The second data line DL2 may be disposed at the left side of the second pixel P2, and the reference line RL may be disposed between the right side of the second pixel P2 and the left side of the third pixel P3. The third data line DL3 may be disposed at the right side of the third pixel P3. The fourth data line DL4 may be disposed at the left side of the fourth pixel P4. Even though it is not shown in figures, the driving current line VDD may be disposed at the right side of the fourth pixel P4.

The structure of the light emitting display device according to the sixth embodiment may be very similar to that of the second embodiment. The different feature of the sixth embodiment is that the first data line DL1 and the second data line DL2 may be disposed in the non-emission area NEA. That is, the first data line DL1 connected to the first pixel P1 may be disposed where the driving current line VDD is disposed in the second embodiment, and the second data line DL2 connected to the second pixel P2 may be disposed where the data line DL is disposed in the second embodiment.

Even though it is not shown in cross-sectional view, the cross-sectional structure between the first pixel P1 and the second pixel P2 may have a structure similar to the structure as shown in FIG. 7. The cross-sectional structure of the light emitting display device according to the sixth embodiment may be that the driving current line VDD in FIG. 7 may be replaced with the first data line DL1 and the data line DL in FIG. 7 may be replaced with the second data line DL2.

The light emitting display device according to the second embodiment may have a structure for preventing or mitigating the light leakage problem, by forming light blocking layers having inclined angle to the vertical direction with respect to the plan surface of the substrate 110 at the non-emission area NEA between neighboring two pixels. Here, the light blocking layers may include a first layer and a second layer stacked each other. The first layer may be made at the same layer as the light shielding layer LS that prevents lights from entering into the semiconductor layer SA and DA. The first auxiliary line M31 and the second auxiliary line M33 may be metal layers by which any signals are not supplied. In the sixth embodiment, the first layer may include the first data line DL1 and the second data line DL2 formed at the same layer as the light shielding layer LS. The second layer may include the first auxiliary line M31 and the second auxiliary line M33 made of the metal material used from the gate electrodes SG and DG (as shown in FIG. 7).

The embodiments described above may be combined with each other to implement another embodiment. For example, the structure of the fourth embodiment or the structure of the fifth embodiment may be applied to the structure of the fifth embodiment. In addition, the fourth embodiment may be applied to the sixth embodiment.

In the embodiments described above, the light emitting display device having two light blocking layers arranged in a parallel manner in a non-emission area NEA is explained as an example. However, it is not limited thereto, one light blocking layer may be disposed at the non-emission area NEA. For example, only one signal line, the reference line RL may be disposed at the non-emitting area NEA between the second pixel SP2 and the third pixel SP3 shown in FIG. 11. In this case, the light blocking layer having an angle inclined in a vertical direction with respect to the surface of the substrate 110 may be formed. For example, the light blocking layer may be formed using a pattern layer, the reference line RL and an auxiliary line so that the light blocking layer may have the same structure as the data line DL and the first auxiliary line M31 shown in FIG. 7.

According to the first embodiment to the third embodiment, the light emitting display device may be a bankless structure without bank. Here, the bank means an insulating layer covering circumferences of the anode electrode ANO to expose middle portions of the anode electrode ANO. The bank may be called as a pixel defining layer. In the light emitting display device according to the present disclosure, the bank may be removed. However, it is not limited thereto, the bank may be disposed at the upper side and the lower side of the pixel where the driving element is disposed, and the bank is not disposed at the left side and the right side of the pixel. In addition, for the case that the bank is formed as covering all circumference areas of the pixel, the mirror structure according to the present disclosure may be applied. In this disclosure, the bankless structure, has been explained for which has advantages for low power consumption and may ensure the maximum aperture ratio.

The light emitting display device according to the present disclosure may comprises: a substrate, an emission area, a non-emission area, a planarization layer, a light blocking layer, an anode electrode, an emission layer and a cathode electrode. The substrate has a plurality of pixels. The emission area is disposed in each pixel. The non-emission area is disposed around the emission area. The planarization layer is disposed on the substrate, and has a flat portion corresponding to the non-emission area and a protrusion portion corresponding to the emission area on the flat portion. The light blocking layer is disposed between the planarization layer and substrate at the non-emission area, and has an inclined angle with respect to a surface of the substrate. The anode electrode is disposed on a top surface of the protrusion portion. The emission layer is disposed on the anode electrode. The cathode electrode is disposed on the emission layer.

In one example, the light blocking layer includes a first light blocking layer disposed at the non-emission area and a second light blocking layer near to the first light blocking layer in the non-emission area.

In one example, the first light blocking layer has a line shape along one side of the emission area. The second light blocking layer is parallel to the first light emitting layer with a predetermined distance.

In one example, the light emitting display device further comprises a pattern layer having a first height and disposed between the light blocking layer and the substrate. The light blocking layer includes a first layer on one side of the pattern layer.

In one example, the light emitting display device further comprises an insulating layer covering an entire surface of the substrate and exposing the first layer. The light blocking layer further includes a second layer covering a sidewall of an open hole exposing the insulating layer, the second layer contacting the first layer.

In one example, the first layer includes a signal line extending from an upper side to a lower side of the substrate. The second layer includes a metal material having a line segment shape corresponding to one side length of the emission area.

In one example, the first layer includes a metal material having a line segment shape corresponding to one side length of the emission area. The second layer includes a signal line extending from an upper side to a lower side of the substrate.

In one example, the light emitting display device further comprises a trench recessed into the substrate and extending from an upper side to a lower side of the substrate along one side of the pixel. The light blocking layer includes a first layer disposed on any one sidewall of the trench.

In one example, the light emitting display device further comprises an insulating layer covering an entire surface of the substrate and exposing the first layer. The light blocking layer further includes a second layer covering a sidewall of an open hole exposing the first layer, the second layer contacting the first layer.

In one example, the first layer includes a signal line extending from an upper side to a lower side of the substrate. The second layer includes a metal material having a line segment shape corresponding to one side length of the emission area.

In one example, the light emitting display device further comprises a passivation layer disposed under the planarization layer and covering the light blocking layer, and a color filter disposed between the passivation layer and the planarization layer.

In one example, the protrusion portion of the planarization layer has a first refractive index with a difference of less than 0.2 from a refractive index of the anode electrode. The flat portion of the planarization layer has a second refractive index lower than the first refractive index.

In one example, the light blocking layer blocks lights provided from adjacent pixels near to a first pixel, among the plurality of pixels, from entering into the first pixel after reflecting by the substrate.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified to employ concepts of the various patents, applications and publications to provide yet further embodiments.

These and other changes can be made to the above example embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

What is claimed is:

1. A light emitting display device, comprising:
a substrate having a plurality of pixels;
an emission area disposed in each of the plurality of pixels;
a non-emission area disposed around the emission area;
a planarization layer disposed on the substrate, and having a flat portion corresponding to the non-emission area and a protrusion portion corresponding to the emission area on the flat portion;
a light blocking layer disposed between the planarization layer and substrate at the non-emission area, and having an inclined angle with respect to a surface of the substrate;
an anode electrode disposed on a top surface of the protrusion portion;
an emission layer on the anode electrode; and
a cathode electrode on the emission layer.

2. The light emitting display device of claim 1, wherein the light blocking layer includes:
a first light blocking layer disposed at the non-emission area; and
a second light blocking layer near to the first light blocking layer in the non-emission area.

3. The light emitting display device of claim 2, wherein the first light blocking layer has a line shape along one side of the emission area, and
wherein the second light blocking layer is parallel to the first light emitting layer with a predetermined distance.

4. The light emitting display device of claim 1, further comprising:
a pattern layer having a first height and disposed between the light blocking layer and the substrate,
wherein the light blocking layer includes a first layer on one side of the pattern layer.

5. The light emitting display device of claim 4, further comprising:
an insulating layer covering an entire surface of the substrate and exposing the first layer,
wherein the light blocking layer further includes a second layer covering a sidewall of an open hole exposing the insulating layer, the second layer contacting the first layer.

6. The light emitting display device of claim 5, wherein the first layer includes a signal line extending from an upper side to a lower side of the substrate, and
wherein the second layer includes a metal material having a line segment shape corresponding to one side length of the emission area.

7. The light emitting display device of claim 5, wherein the first layer includes a metal material having a line segment shape corresponding to one side length of the emission area, and
wherein the second layer includes a signal line extending from an upper side to a lower side of the substrate.

8. The light emitting display device of claim 1, further comprising:
a trench recessed into the substrate and extending from an upper side to a lower side of the substrate along one side of a pixel among the plurality of pixels,
wherein the light blocking layer includes a first layer disposed on any one sidewall of the trench.

9. The light emitting display device of claim 8, further comprising:
an insulating layer covering an entire surface of the substrate and exposing the first layer,
wherein the light blocking layer further includes a second layer covering a sidewall of an open hole exposing the first layer, the second layer contacting the first layer.

10. The light emitting display device of claim 9, wherein the first layer includes a signal line extending from an upper side to a lower side of the substrate, and
wherein the second layer includes a metal material having a line segment shape corresponding to one side length of the emission area.

11. The light emitting display device of claim 1, further comprising:
a passivation layer disposed under the planarization layer and covering the light blocking layer; and
a color filter disposed between the passivation layer and the planarization layer.

12. The light emitting display device of claim 1, wherein the protrusion portion of the planarization layer has a first refractive index with a difference of less than 0.2 from a refractive index of the anode electrode, and
wherein the flat portion of the planarization layer has a second refractive index lower than the first refractive index.

13. The light emitting display device of claim 1, wherein the light blocking layer blocks lights provided from adjacent pixels near to a first pixel, among the plurality of pixels, from entering into the first pixel after reflecting by the substrate.
